(19) United States
(12) Patent Application Publication
(10) Pub. No.: US 2008/0237842 A1
(43) Pub. Date: Oct. 2, 2008

(54) Thermally conductive molding compounds for heat dissipation in semiconductor packages

(76) Inventor: Rahul N. Manepalli, Chandler, AZ (US)

Correspondence Address: CAVEN & AGHEVLI;c/o INTELLEVATE, LLC, P.O. BOX 52050, MINNEAPOLIS, MN, 55402, US

(21) Appl. No.: 11/729,494

(22) Filed: Mar. 29, 2007

(51) Int. Cl. H01L 23/373

(52) U.S. Cl. 257/712; 257/E23.112

(57) ABSTRACT

Methods and apparatus relating to thermally conductive molding compounds are described. In one embodiment, a molding compound may include thermally conductive particles to form a thermally conductive path in the molding compound (e.g., for improved heat dissipation through the molding compound). Other embodiments are also described.

### BACKGROUND

The present disclosure generally relates to the field of electronics. More particularly, an embodiment of the invention relates to thermally conductive molding compounds.

Integrated circuit (IC) devices may generate heat during operation. Excessive heat may cause damage to IC devices. To remove heat from some IC devices, a thermal interface material and a heat spreader may be used. However, IC devices that employ such techniques may be much larger in size and unsuitable for small form-factor electronic devices, such as handheld computing devices.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates a cross-sectional view of a semiconductor package, according to one embodiment of the invention.

FIGS. 2-3 illustrate views of molding compound particles, according to some embodiments of the invention.

FIG. 4 illustrates a block diagram of a method according to an embodiment.

FIG. 5 illustrates a block diagram of a computing system, which may be utilized to implement various embodiments discussed herein.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

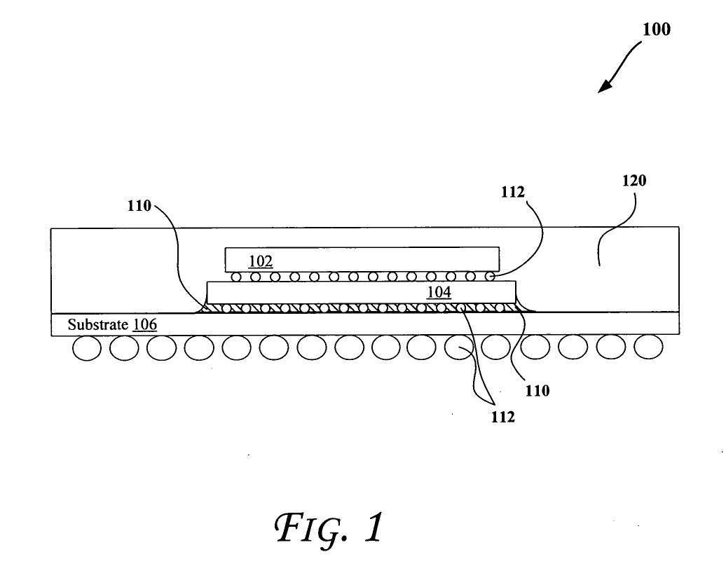

Some of the embodiments discussed herein (such as the embodiments discussed with reference to FIGS. 1-5) may provide a molding compound that efficiently conducts thermal energy. In an embodiment, use of the molding compound may enable small form factor flip chip packages that are more efficient at dissipating heat. More particularly, FIG. 1 illustrates a cross-sectional view of a semiconductor package 100, according to one embodiment of the invention. The package 100 may include one or more dies (e.g., dies 102 and 104) that may be stacked on a substrate 106. In one embodiment, die 102 may be flipped prior to coupling it with the diet 104. Accordingly, in one embodiment of the invention, the package 100 may be a flip-chip package.

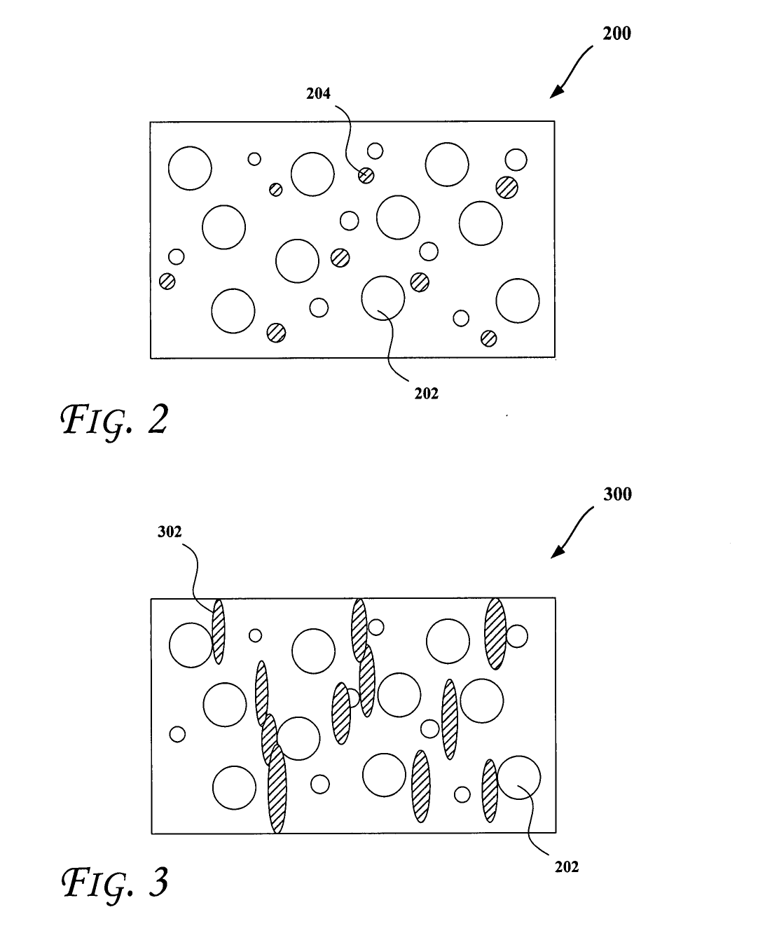

As shown in FIG. 1, underfill 110 may be provided between the substrate 106 and die 104 (which may be constructed with material such as epoxy in an embodiment). In one embodiment, underfill 110 may also be provided between the dies 102 and 104. Furthermore, solder bumps 112 may couple various components of the package 100, such as dies 102 and 104, die 104 and substrate 106, substrate 106 to other components such as a motherboard (not shown), etc. Additionally, in some embodiments, a molding compound 120 may be provided over the substrate 106, e.g., to provide package stiffness, provide a protective or hermetic cover, provide shielding, provide package stiffness, and/or provide a heat conductive path. In an embodiment, the molding compound 120 may be provided to mechanically couple various components of the package 100, including, for example, the dies 102-104, substrate 106, and/or underfill 110. Molding compound 120 may be constructed with material such as epoxy, epoxy with non-thermally conductive particles (such as silica particles), organic cylinders, plastic molding compound, plastic molding compound with fiber, etc. As will be further discussed with reference to FIGS. 2-3, the molding compound 120 may also include thermally conductive particles in accordance with some embodiments.

FIGS. 2-3 illustrate views of molding compound particles, according to some embodiments of the invention. In some embodiments, molding compound 200 of FIG. 2 may be the same as or similar to the molding compound 120 of FIG. 1. Referring to FIG. 2, molding compound 200 may include two different types of particles. Particles 202 (shown in FIGS. 2 and 3 as empty circles) may be particles from material such as epoxy, epoxy with non-thermally conductive particles (such as silica particles), organic cylinders, plastic molding compound, plastic molding compound with fiber, etc. Particles 204 (shown in FIGS. 2 and 3 as circles with shading) may be thermally conductive particles, such as particles from material including, for example, metallic material (e.g., aluminum, copper, silver, gold, AlN, Al₂O₃, or combinations thereof) or other thermally conductive material. In an embodiment, particles 204 may be particles of solder material, such as a fusible metal alloy, including, for example, tin, lead, copper, antimony, silver, or combinations thereof.

In an embodiment, the particles 202 may not be as efficient at thermal conduction as particles 204. Further, in at least one embodiment, the solder material may be in powder form and the powder may be added to the material that includes particles 202 as filler prior to curing the molding compound. Accordingly, presence of particles 204 in the molding compound 200 may improve the thermal conductivity of the compound 200.

Referring to FIG. 3, molding compound 300 may include particles 202 and particles 302. In some embodiments, molding compound 300 of FIG. 2 may be the same as or similar to the molding compound 120 of FIG. 1. Additionally, molding compound 300 illustrates that particles 204 of FIG. 2 may be modified into particles 302, e.g., after heat is applied to the molding compound 200, resulting in fusing of the particles 204 at least partially. For example, in the embodiment that uses solder material to provide particles 204, the particles 302 may be present after the reflow temperature of the particles 204 is reached. Accordingly, particles 302 may form a conduction path post curing of the molding compound 300 in some embodiments. In accordance with some embodiments, the presence of particles 204 and 302 in the molding compounds 200 and 300, respectively, may improve the thermal conductivity of these compounds. In at least one embodiment, three types of particles may be present in the molding compound 120 of FIG. 1, including, for example, particles 202, 204, and 302.

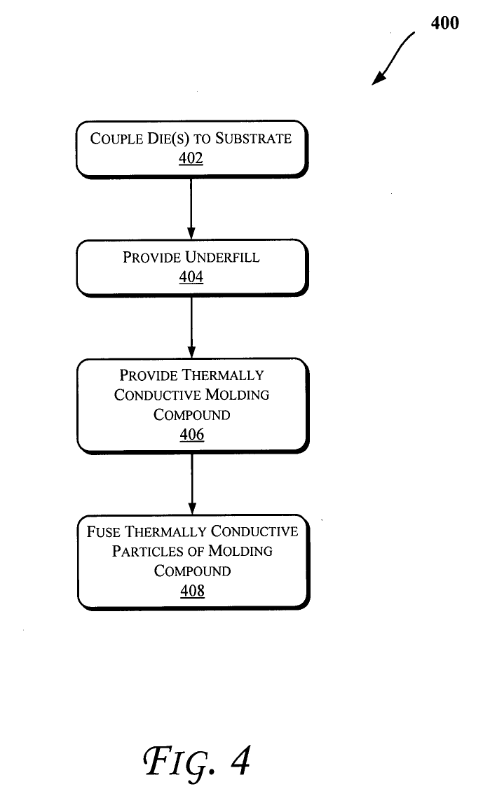

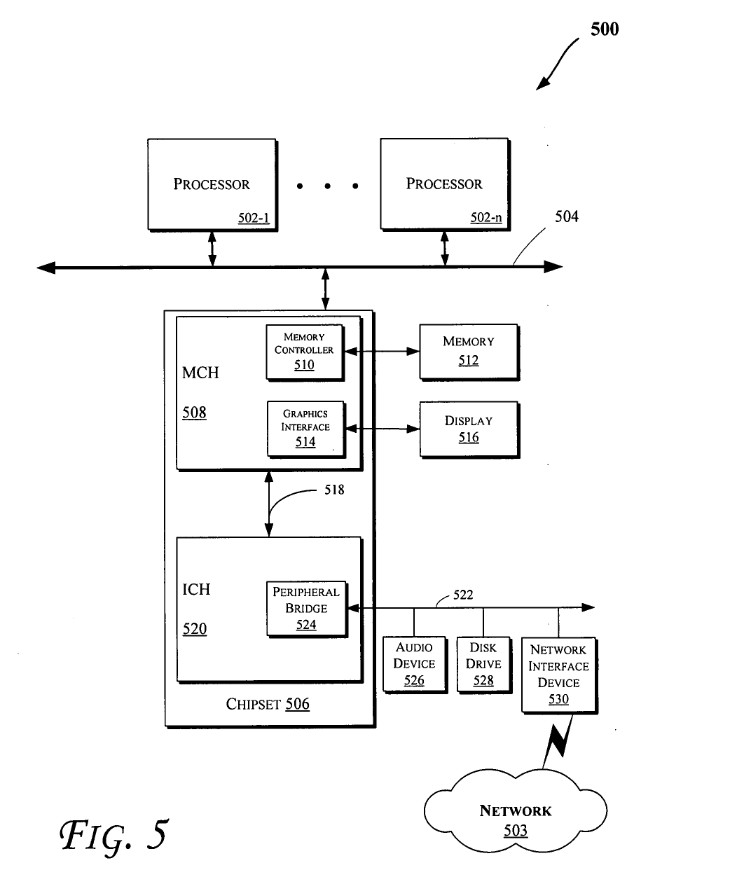

FIG. 4 illustrates a block diagram of an embodiment of a method 400 to provide a semiconductor package with a thermally conductive molding compound. In an embodiment, various components discussed with reference to FIGS. 1-3 and 5 may be utilized to perform one or more of the operations discussed with reference to FIG. 4. For example, the method 400 may be used to provide the package 100 of FIG. 1 or one or more components of the system 500 of FIG. 5.

Referring to FIGS. 1-4, at an operation 402, one or more dies are coupled to a semiconductor substrate (e.g., dies 102 and/or 104 are coupled to the substrate 106, for example, via solder bumps 112). At an operation 404, an underfill may be provided (e.g., underfill 110 may be provided to couple the die 104 and the substrate 106 and/or dies 102 and 104). At an operation 406, a thermally conductive molding compound may be provided (e.g., the compounds 120, 200, and/or 300 may be provided to couple various components of the package 100 such as discussed herein, e.g., with reference to FIGS. 1-4). At an operation 408, thermally conductive particles of the molding compound may be fused, e.g., to provide a thermally conductive path within the molding compound. In an embodiment, the molding compound (that includes solder material) may be heated to the reflow temperature of the thermally conductive particles at operation 408. Moreover, as discussed with reference to FIG. 2, particles 204 may improve thermal conductivity of the molding compound 200 (e.g., even before the particles are fused such as discussed with reference to particles 302 of FIG. 3). Thus, operation 408 may be optional in some embodiments.

In some embodiments, thin die, flip chip packages may be used as a packaging solution to enable small form factor packaging of high density, high power flip chip devices. In one embodiment, thin die packages may be under-filled and/or over-molded in order to provide robustness with handling and/or to minimize any cracking of the thin die during processing. The higher thermal conductivity of the molding compound discussed herein may improve heat dissipation from the semiconductor package, e.g., enabling the use of such technologies for high power devices.

Further, some embodiments may enable: (a) dissipation of a higher amount of heat in thin die over molded packages; (b) use of available flip chip processing, molding infrastructure to enable a low cost high through put package; and/or (c) creation of an in-situ thermally conductive path in the molding compound to minimize thermal resistance from a semiconductor package (e.g., top of the dies 102 and/or 104 of FIG. 1) to external world. Also, the particles 302 of FIG. 3 may form a continuous path for heat conduction through the molding compound 300 of FIG. 3 in some embodiments.

FIG. 5 illustrates a block diagram of a computing system 500 in accordance with an embodiment of the invention. The computing system 500 may include one or more central processing unit(s) (CPUs) 502 or processors that communicate via an interconnection network (or bus) 504 one. The processors 502 may include a general purpose processor, a network processor (that processes data communicated over a computer network 503), or other types of a processor (including a reduced instruction set computer (RISC) processor or a complex instruction set computer (CISC)). Moreover, the processors 502 may have a single or multiple core design. The processors 502 with a multiple core design may integrate different types of processor cores on the same integrated circuit (IC) die. Also, the processors 502 with a multiple core design may be implemented as symmetrical or asymmetrical multiprocessors. Moreover, the operations discussed with reference to FIGS. 1-4 may be performed by one or more components of the system 500.

A chipset 506 may also communicate with the interconnection network 504. The chipset 506 may include a memory control hub (MCH) 508. The MCH 508 may include a memory controller 510 that communicates with a memory 512. The memory 512 may store data, including sequences of instructions that are executed by the CPU 502, or any other device included in the computing system 500. In one embodiment of the invention, the memory 512 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 504, such as multiple CPUs and/or multiple system memories.

The MCH 508 may also include a graphics interface 514 that communicates with a display 516. In one embodiment of the invention, the graphics interface 514 may communicate with the display 516 via an accelerated graphics port (AGP). In an embodiment of the invention, the display 516 may be a flat panel display that communicates with the graphics interface 514 through, for example, a signal converter that translates a digital representation of an image stored in a storage device such as video memory or system memory into display signals that are interpreted and displayed by the display 516. The display signals produced by the interface 514 may pass through various control devices before being interpreted by and subsequently displayed on the display 516.

A hub interface 518 may allow the MCH 508 and an input/output control hub (ICH) 520 to communicate. The ICH 520 may provide an interface to I/O devices that communicate with the computing system 500. The ICH 520 may communicate with a bus 522 through a peripheral bridge (or controller) 524, such as a peripheral component interconnect (PCI) bridge, a universal serial bus (USB) controller, or other types of peripheral bridges or controllers. The bridge 524 may provide a data path between the CPU 502 and peripheral devices. Other types of topologies may be utilized. Also, multiple buses may communicate with the ICH 520, e.g., through multiple bridges or controllers. Moreover, other peripherals in communication with the ICH 520 may include, in various embodiments of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 522 may communicate with an audio device 526, one or more disk drive(s) 528, and a network interface device 530 (which is in communication with the computer network 503). Other devices may communicate via the bus 522. Also, various components (such as the network interface device 530) may communicate with the MCH 508 in some embodiments of the invention. In addition, the processor 502 and the MCH 508 may be combined to form a single chip. Furthermore, the graphics interface 514 may be included within the MCH 508 in other embodiments of the invention.

Furthermore, the computing system 500 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 528), a floppy disk, a compact disk ROM (CD-ROM), a digital versatile disk (DVD), flash memory, a magneto-optical disk, or other types of nonvolatile machine-readable media that are capable of storing electronic data (e.g., including instructions). In an embodiment, components of the system 500 may be arranged in a point-to-point (PtP) configuration. For example, processors, memory, and/or input/output devices may be interconnected by a number of point-to-point interfaces.

In various embodiments of the invention, the operations discussed herein, e.g., with reference to FIGS. 1-5, may be implemented as hardware (e.g., logic circuitry), software, firmware, or combinations thereof, which may be provided as a computer program product, e.g., including a machine-readable or computer-readable medium having stored thereon instructions (or software procedures) used to program a computer to perform a process discussed herein. The machine-readable medium may include a storage device such as those discussed with respect to FIG. 5.

Additionally, such computer-readable media may be downloaded as a computer program product, wherein the program may be transferred from a remote computer (e.g., a server) to a requesting computer (e.g., a client) by way of data signals embodied in a carrier wave or other propagation medium via a communication link (e.g., a bus, a modem, or a network connection). Accordingly, herein, a carrier wave shall be regarded as comprising a machine-readable medium.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. An apparatus comprising:
a molding compound having a plurality of thermally conductive particles to form a thermally conductive path in the molding compound, wherein the molding compound is disposed over at least a portion of a substrate and a semiconductor die coupled with the substrate.

2. The apparatus of claim 1, wherein the thermally conductive particles comprise particles from one or more of metallic material or solder material.

3. The apparatus of claim 2, wherein the metallic material comprises one or more of aluminum, copper, silver, gold, AlN, Al₂O₃, or combinations thereof.

4. The apparatus of claim 2, wherein the solder material comprises one or more of tin, lead, copper, antimony, silver, or combinations thereof.

5. The apparatus of claim 2, wherein the solder material is reflowed to fuse at least some of the plurality of thermally conductive particles together, wherein the fused particles form the thermally conductive path in the molding compound.

6. The apparatus of claim 1, wherein the molding compound is to couple one or more components of a semiconductor package and wherein the components of the semiconductor package comprise one or more of the substrate and a plurality of semiconductor dies.

7. The apparatus of claim 6, wherein the plurality of dies are coupled through one or more solder bumps.

8. The apparatus of claim 1, wherein the substrate and the die are coupled through one or more solder bumps.

9. The apparatus of claim 1, further comprising an underfill to couple the substrate and the die.

10. The apparatus of claim 1, wherein the molding compound further comprises a plurality of particles that is less thermally conductive than the thermally conductive particles.

11. The apparatus of claim 1, wherein the molding compound is to couple one or more of: a single-core processor, a multi-core processor, a memory device, a network communication device, or a chipset.

12. An apparatus comprising:
a substrate having a first surface and an opposing second surface;
an integrated circuit die disposed on the substrate first surface; and
a mold compound disposed over at least a portion of the die and the substrate first surface, the mold compound having a plurality of thermally conductive particles to form a thermally conductive path in the mold compound.

13. The apparatus of claim 12, wherein the thermally conductive particles comprise particles from one or more of metallic material or solder material.

14. The apparatus of claim 13, wherein the metallic material comprises one or more of aluminum, copper, silver, gold, AlN, Al₂O₃, or combinations thereof.

15. The apparatus of claim 13, wherein the solder material comprises one or more of tin, lead, copper, antimony, silver, or combinations thereof.
